(19) United States
(12) Patent Application Publication
(10) Pub. No.: US 2021/0408050 A1
(43) Pub. Date: Dec. 30, 2021

(54) ARRAY SUBSTRATE AND DISPLAY PANEL

(71) Applicant: SHENZHEN CHINA STAR OPTOELECTRONICS SEMICONDUCTOR DISPLAY TECHNOLOGY CO., LTD., Shenzhen, Guangdong (CN)

(72) Inventors: Suping XI, Shenzhen, Guangdong (CN); Tianhong WANG, Shenzhen, Guangdong (CN)

(21) Appl. No.: 16/621,265

(22) PCT Filed: Nov. 6, 2019
(86) PCT No.: PCT/CN2019/115848

§ 371 Date: Dec. 11, 2019

(30) Foreign Application Priority Data
Aug. 8, 2019 (CN) 201910729704.5

(51) Int. Cl. H01L 27/12; G09G 3/36

(52) U.S. Cl. CPC H01L 27/124; H01L 27/1255; G09G 3/3677

(57) ABSTRACT

The present application provides an array substrate and a display panel. The array substrate comprises: a substrate; a first metal layer; a first insulating layer; a second metal layer disposed on the first insulating layer, the second metal layer forming a scan line, a first connection metal, and a first drain of the first thin film transistor; a second insulating layer; a third metal layer disposed on the second insulating layer, the third metal layer being electrically connected to the first gate, and a portion of the third metal layer opposite to the first connecting metal forms a bootstrap capacitor.

### BACKGROUND OF INVENTION

### Field of Invention

The present application relates to the field of display technology, and particularly, to an array substrate and a display panel.

### Description of Prior Art

Gate driver on array (GOA) is a method of fabricating a gate row scan driving signal circuit on an array substrate by using an array substrate process in an existing thin film transistor liquid crystal display to realize a gate-by-row scanning driving mode.

GOA technology can achieve narrow borders or even borderless design, which can increase TV customer process design choices and expand product application fields (for example, public splicing display fields). However, the existing display panel cannot achieve a narrower border due to the large area occupied by the GOA driving circuit.

### SUMMARY OF INVENTION

The object of the embodiment of the present application is to provide an array substrate and a display panel, which can solve the technical problem that the existing display panel can not achieve a narrower border due to the large region occupied by the GOA driving circuit.

The embodiment of the present application provides an array substrate, wherein the array substrate is provided with a gate driver on array (GOA) driving circuit and a plurality of pixel units, the GOA driving circuit comprises a bootstrap capacitor and a first thin film transistor, and the pixel units comprise a second thin film transistor, the array substrate comprising: a substrate; a first metal layer disposed on the substrate, wherein the first metal layer forms a first gate of the first thin film transistor and a second gate of the second thin film transistor; a first insulating layer disposed on the first metal layer and the substrate; a second metal layer disposed on the first insulating layer, wherein the second metal layer forms a scan line, a first connecting metal, and a first drain of the first thin film transistor, and wherein the first drain, the first connection metal, and one end of the scan line are sequentially connected, and the other end of the scan line is connected to the second gate; a second insulating layer disposed on the second metal layer; and a third metal layer disposed on the second insulating layer, wherein the third metal layer is electrically connected to the first gate, and a portion of the third metal layer opposite to the first connecting metal forms the bootstrap capacitor; wherein the first metal layer is further formed with a common electrode line that is electrically connected to the pixel units, the first insulating layer is provided with at least one fourth metallized hole, and the scan line is electrically connected to the second gate through the fourth metallized hole.

In the array substrate of the present application, a portion of the first connecting metal is opposite to the common electrode line.

In the array substrate of the present application, the third metal layer comprises a first region and a second region that are connected to each other, the first region and the first connecting metal have same shape and size and face each other, and the second region is electrically connected to the first gate.

In the array substrate of the present application, the second region is electrically connected to the first gate through a third metallized hole penetrating the first insulating layer and the second insulating layer.

In the array substrate of the present application, the second metal layer is further formed with a second connecting metal, the first insulating layer is provided with at least one first metallized hole, and the second insulating layer is provided with at least one second metallized hole, and the second region, the second metallized hole, the second connection metal, the first metallized hole, and the first gate are electrically connected in sequence.

In the array substrate of the present application, the at least one first metallized hole comprises a plurality of first metallized holes arranged in a rectangular array, and the at least one second metallized hole comprises a plurality of second metallized holes arranged in a rectangular array.

In the array substrate of the present application, the at least one fourth metallized hole comprises a plurality of fourth metallized holes arranged in a rectangular array.

The embodiment of the present application also provides an array substrate, wherein the array substrate is provided with a gate driver on array (GOA) driving circuit and a plurality of pixel units, the GOA driving circuit comprises a bootstrap capacitor and a first thin film transistor, and the pixel units comprise a second thin film transistor, the array substrate comprising: a substrate; a first metal layer disposed on the substrate, wherein the first metal layer forms a first gate of the first thin film transistor and a second gate of the second thin film transistor; a first insulating layer disposed on the first metal layer and the substrate; a second metal layer disposed on the first insulating layer, wherein the second metal layer forms a scan line, a first connecting metal, and a first drain of the first thin film transistor, and wherein the first drain, the first connection metal, and one end of the scan line are sequentially connected, and the other end of the scan line is connected to the second gate; a second insulating layer disposed on the second metal layer; and a third metal layer disposed on the second insulating layer, wherein the third metal layer is electrically connected to the first gate, and a portion of the third metal layer opposite to the first connecting metal forms the bootstrap capacitor.

In the array substrate of the present application, the first metal layer is further formed with a common electrode line that is electrically connected to the pixel units.

In the array substrate of the present application, a portion of the first connecting metal is opposite to the common electrode line.

In the array substrate of the present application, the third metal layer comprises a first region and a second region that are connected to each other, the first region and the first connecting metal have same shape and size and face each other, and the second region is electrically connected to the first gate.

In the array substrate of the present application, the second region is electrically connected to the first gate through a third metallized hole penetrating the first insulating layer and the second insulating layer.

In the array substrate of the present application, the second metal layer is further formed with a second connecting metal, the first insulating layer is provided with at least one first metallized hole, and the second insulating layer is provided with at least one second metallized hole, and the second region, the second metallized hole, the second connection metal, the first metallized hole, and the first gate are electrically connected in sequence.

In the array substrate of the present application, the at least one first metallized hole comprises a plurality of first metallized holes arranged in a rectangular array; and the at least one second metallized hole comprises a plurality of second metallized holes arranged in a rectangular array.

In the array substrate of the present application, the first insulating layer is provided with at least one fourth metallized hole, and the scan line is electrically connected to the second gate through the fourth metallized hole.

In the array substrate of the present application, the at least one fourth metallized hole comprises a plurality of fourth metallized holes arranged in a rectangular array.

The application also provides a display panel comprising an array substrate, wherein the array substrate is provided with a gate driver on array (GOA) driving circuit and a plurality of pixel units, the GOA driving circuit comprises a bootstrap capacitor and a first thin film transistor, and the pixel units comprise a second thin film transistor, the array substrate comprising: a substrate; a first metal layer disposed on the substrate, wherein the first metal layer forms a first gate of the first thin film transistor and a second gate of the second thin film transistor; a first insulating layer disposed on the first metal layer and the substrate; a second metal layer disposed on the first insulating layer, wherein the second metal layer forms a scan line, a first connection metal, and a first drain of the first thin film transistor, and wherein the first drain, the first connection metal, and one end of the scan line are sequentially connected, and the other end of the scan line is connected to the second gate; a second insulating layer disposed on the second metal layer; and a third metal layer disposed on the second insulating layer, wherein the third metal layer is electrically connected to the first gate, and a portion of the third metal layer opposite to the first connecting metal forms the bootstrap capacitor.

In the display panel of the present application, the first metal layer is further formed with a common electrode line that is electrically connected to the pixel unit.

In the display panel of the present application, a portion of the first connecting metal is opposite to the common electrode line.

In the display panel of the present application, the third metal layer comprises a first region and a second region that are connected to each other, the first region and the first connecting metal have same shape and size and face each other, and the second region is electrically connected to the first gate.

The array substrate and the display panel of the embodiment of the present application form the bootstrap capacitor by forming the third metal layer opposite to the first connection metal on the third insulation layer, without extending the width of the first metal layer, to form the bootstrap capacitor with the first connection metal, so that the area occupied by the GOA driving circuit can be reduced, thereby achieving a narrower border.

### BRIEF DESCRIPTION OF DRAWINGS

In order to more clearly illustrate the embodiments of the present application or the technical solutions in the prior art, the drawings used in the embodiments will be briefly described below. The drawings in the following description are only partial embodiments of the present application, and those skilled in the art can obtain other drawings according to the drawings without any creative work.

FIG. 1 is a schematic plan view of an array substrate according to an embodiment of the present application.

FIG. 2 is a schematic structural diagram of an array substrate according to an embodiment of the present application.

FIG. 3 is a schematic structural diagram of a partial region of an array substrate according to an embodiment of the present application.

FIG. 4 is another schematic structural diagram of an array substrate according to an embodiment of the present application.

### DETAILED DESCRIPTION OF PREFERRED EMBODIMENTS

The embodiments of the present application are described in detail below, and the examples of the embodiments are illustrated in the drawings, wherein the same or similar reference numerals are used to refer to the same or similar elements or elements having the same or similar functions. The embodiments described below with reference to the accompanying drawings are intended to be illustrative, and are not to be construed as limiting.

In the description of the present application, it is to be understood that the terms “center”, “longitudinal”, “transverse”, “length”, “width”, “thickness”, “upper”, “lower”, “front”, “post”, “left”, “right”, “vertical”, “horizontal”, “top”, “bottom”, “inside”, “outside”, “clockwise”, “counterclockwise”, etc. refer to positional relationship based on the orientational or positional relationship shown in the drawings, and are merely for the convenience of describing the present application and the simplified description, and does not indicate or imply that the device or component referred to has a specific orientation, and is constructed and operated in a specific orientation. Therefore, it should not be construed as limiting the application. Moreover, the terms “first” and “second” are used for descriptive purposes only and are not to be construed as indicating or implying a relative importance or implicitly indicating the number of technical features indicated. Thus, features defining “first” or “second” may include one or more of the described features either explicitly or implicitly. In the description of the present application, the meaning of “plurality” is two or more, unless specifically defined otherwise.

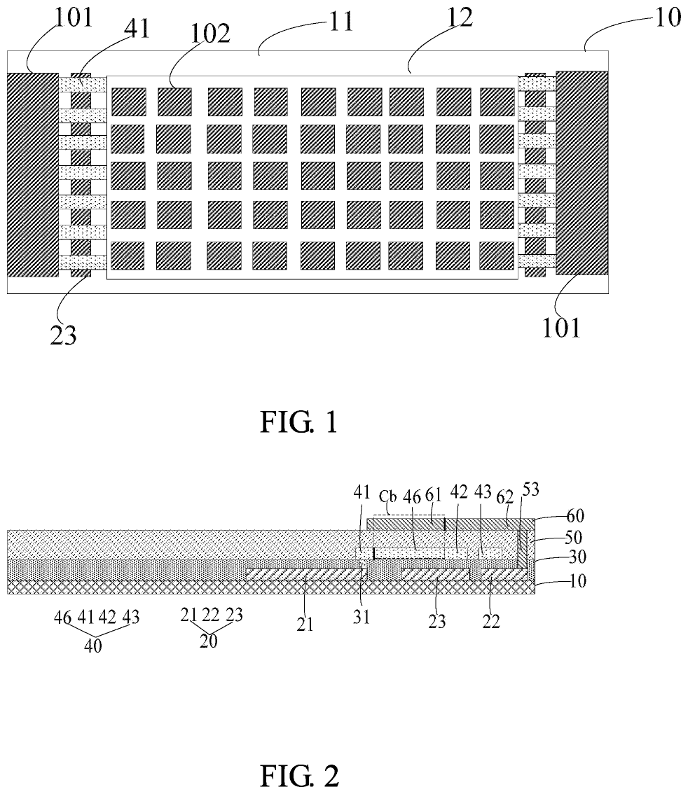

Please refer to FIG. 1, FIG. 1 is a schematic plan view of an array substrate according to an embodiment of the present application. From the perspective of the layout level, the array substrate comprises a substrate 10, a gate driver on array (GOA) driving circuit 101 disposed on the substrate 10, and a plurality of pixel units 102. Wherein, the substrate 10 comprises a display region 12 and a non-display region 11, and the non-display region 11 is disposed around the display region 12. Wherein, the GOA driving circuit 101 is disposed in the non-display region 11, and the plurality of pixel units 102 are disposed in the display region 12.

Wherein, the circuit principle of the GOA driving circuit 101 is the same as that of the GOA driving circuit in the prior art, and comprise a pull-up control module, a pull-up maintenance module, a pull-up module, a bootstrap capacitor, a pull-down control module, and a pull-down module. As they are well-established prior art, there is no need for detailed description. The pull-up control module generally adopts a field effect thin film transistor, which is a first thin film transistor in the present invention. The bootstrap capacitor is formed by directly facing a two-layer metal block, and the formation of the bootstrap capacitor will be described in detail later. Wherein, the pixel units 102 have the same structure as pixel units in the prior art, and comprise a second thin film transistor and other components for controlling the switch of one entire pixel unit 102. For example, the pixel unit 102 further comprises a storage capacitor, a light emitting element, and the like, all of which are prior art and do not need to be described in detail.

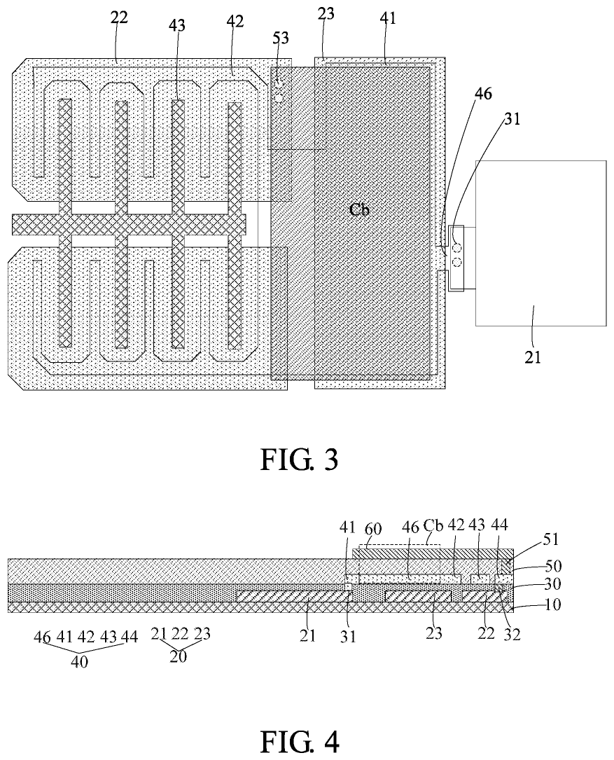

Specifically, please refer to FIG. 2 and FIG. 3 simultaneously. FIG. 2 is a schematic structural diagram of an array substrate according to an embodiment of the present application, and FIG. 3 is a schematic structural diagram of a partial region of an array substrate according to an embodiment of the present application.

In terms of vertical layer structure, the array substrate comprises a first metal layer 20, a first insulating layer 30, a second metal layer 40, a second insulating layer 50, and a third metal layer 60, in addition to a substrate 10. Of course, a semiconductor layer is also provided therein, and the position of the semiconductor layer is not particularly limited. The first metal layer 20, the first insulating layer 30, the second metal layer 40, the second insulating layer 50, the third metal layer 60, and the semiconductor layer respectively form a GOA driving circuit located in the non-display region 11 by a plurality of mask processes and a plurality of pixel units 102 located in the display region 12.

Wherein, the substrate 10 is a glass substrate, and of course, a substrate of other materials may also be used.

Wherein, the first metal layer 20 is deposited on the substrate 10, and the first metal layer 10 forms a first gate 22 of the first thin film transistor, a second gate 21 of the second thin film transistor, and a common electrode line 23 by a photomask process. The common electrode line 23 is electrically connected to each of the pixel units 102 for supplying a common voltage to each of the pixel units 102. Wherein, the first gate 22 and the common electrode line 23 are in the non-display region 12, and the second gate 21 is in the display region 11.

Wherein, in some embodiments, the first insulating layer 30 is disposed on the first metal layer 20 and the substrate 10; and the first insulating layer 30 is formed by depositing silicon nitride or silicon dioxide.

Wherein, in some embodiments, the second metal layer 40 is disposed on the first insulating layer 30, and the second metal layer 30 forms a scan line 41, a first connection metal 46, a first drain of the first thin film transistor 42, and a first source of the first thin film transistor 43 by adopting a photomask process. The first drain 42, the first connection metal 46, and one end of the scan line 41 are sequentially connected, and the other end of the scan line 41 is connected to the second gate 21. Wherein, the first connecting metal 46, the first drain 42, and the first source 43 are all located in the non-display region 12.

Of course, it can be understood that the first thin film transistor further comprises a first semiconductor layer located in the non-display region 12 and a correspondingly formed first channel structure, which are prior art and do not need to be described in detail. The second thin film transistor further comprises a second source and a second drain formed on the display region 11 and a corresponding channel structure, not shown, which are prior art and need not be described excessively. The second source and the second drain are also formed by the photomask process by the second metal layer 40.

Wherein, the second insulating layer 50 is disposed on the second metal layer 40 and the first insulating layer 30; and the second insulating layer 50 is formed by depositing silicon nitride or silicon dioxide.

Wherein, the third metal layer 60 is disposed on the second insulating layer 50. The third metal layer 60 is electrically connected to the first gate 22. A portion of the third metal layer 60 opposite to the first connecting metal 46 forms a bootstrap capacitor Cb. The third metal layer 60 is made of ITO metal, of course, other transparent metal materials may also be used.

Specifically, in some embodiments, the third metal layer 60 comprises a first region 61 and a second region 62 that are connected to each other, the first region 61 and the first connecting metal 46 have same shape and size and are opposite to each other, and the second region 62 is electrically connected to the first gate 22. The first region 61 and the first connection metal 46 form the bootstrap capacitor Cb in the GOA driving circuit mentioned above. The first region 61 and the first connecting metal 46 are both located directly above the common electrode line 23.

Wherein, in the present embodiment, the second region 62 of the third metal layer 60 is electrically connected to the first gate 22 through a third metallized hole 53 penetrating the first insulating layer 30 and the second insulating layer 50. A number of the third metallized hole 53 may be one or plural. In the embodiment, a plurality of uniformly arranged third metallized holes 53 are used to realize the electrical connection of the second region 62 and the first gate 22 to improve connection stability.

In other embodiments, the second region 62 of the third metal layer 60 and the first gate 22 may also be electrically connected by other structures. Please refer to FIG. 4, in the embodiment, the second metal layer 40 is further formed with a second connecting metal 44. The first insulating layer 30 is provided with at least one first metallized hole 32, and the second insulating layer 50 is provided with at least one second metallized hole 51. The second region 62, the second metallized hole 51, the second connection metal 44, the first metallized hole 32, and the first gate 22 are electrically connected in sequence. The first region 61 and the first connection metal 46 form the bootstrap capacitor Cb. In this embodiment, the at least one first metallized hole 32 comprises a plurality of first metallized holes 32 arranged in a rectangular array; the at least one second metallized hole 51 comprises a plurality of second metallized holes 51 arranged in a rectangular array, thereby improving the stability of the connection.

Wherein, the first insulating layer 30 is provided with at least one fourth metallized hole 31, and the scan line 41 is electrically connected to the second gate 21 through the fourth metallized hole 31. The at least one fourth metallized hole 31 comprises a plurality of fourth metallized holes 31 arranged in a rectangular array, thereby improving the stability of the electrical connection.

The present invention also provides a display panel comprising the array substrate of any of the above embodiments.

The array substrate and the display panel of the embodiment of the present application form the bootstrap capacitor by forming the third metal layer opposite to the first connection metal on the third insulation layer, without extending the width of the first metal layer, to form the bootstrap capacitor with the first connection metal, so that the area occupied by the GOA driving circuit can be reduced, thereby achieving a narrower border.

The above are only the embodiments of the present invention, and are not intended to limit the scope of the invention, and the equivalent structure or equivalent process transformations made by the description of the present invention and the drawings are directly or indirectly applied to other related technical fields. The same is included in the scope of patent protection of the present invention.

What is claimed is:

1. An array substrate, wherein the array substrate is provided with a gate driver on array (GOA) driving circuit and a plurality of pixel units, the GOA driving circuit comprises a bootstrap capacitor and a first thin film transistor, and the pixel units comprise a second thin film transistor, the array substrate comprising:
a substrate;
a first metal layer disposed on the substrate, wherein the first metal layer forms a first gate of the first thin film transistor and a second gate of the second thin film transistor;
a first insulating layer disposed on the first metal layer and the substrate;
a second metal layer disposed on the first insulating layer, wherein the second metal layer forms a scan line, a first connecting metal, and a first drain of the first thin film transistor, and wherein the first drain, the first connection metal, and one end of the scan line are sequentially connected, and the other end of the scan line is connected to the second gate;
a second insulating layer disposed on the second metal layer; and
a third metal layer disposed on the second insulating layer, wherein the third metal layer is electrically connected to the first gate, and a portion of the third metal layer opposite to the first connecting metal forms the bootstrap capacitor;
wherein the first metal layer is further formed with a common electrode line that is electrically connected to the pixel units, the first insulating layer is provided with at least one fourth metallized hole, and the scan line is electrically connected to the second gate through the fourth metallized hole.

2. The array substrate of claim 1, wherein a portion of the first connecting metal is opposite to the common electrode line.

3. The array substrate of claim 2, wherein the third metal layer comprises a first region and a second region that are connected to each other, the first region and the first connecting metal have same shape and size and face each other, and the second region is electrically connected to the first gate.

4. The array substrate of claim 3, wherein the second region is electrically connected to the first gate through a third metallized hole penetrating the first insulating layer and the second insulating layer.

5. The array substrate of claim 3, wherein the second metal layer is further formed with a second connecting metal, the first insulating layer is provided with at least one first metallized hole, the second insulating layer is provided with at least one second metallized hole, and the second region, the second metallized hole, the second connection metal, the first metallized hole, and the first gate are electrically connected in sequence.

6. The array substrate of claim 5, wherein the at least one first metallized hole comprises a plurality of first metallized holes arranged in a rectangular array, and the at least one second metallized hole comprises a plurality of second metallized holes arranged in a rectangular array.

7. The array substrate of claim 1, wherein the at least one fourth metallized hole comprises a plurality of fourth metallized holes arranged in a rectangular array.

8. An array substrate, wherein the array substrate is provided with a gate driver on array (GOA) driving circuit and a plurality of pixel units, the GOA driving circuit comprises a bootstrap capacitor and a first thin film transistor, and the pixel units comprise a second thin film transistor, the array substrate comprising:
a substrate;
a first metal layer disposed on the substrate, wherein the first metal layer forms a first gate of the first thin film transistor and a second gate of the second thin film transistor;
a first insulating layer disposed on the first metal layer and the substrate;
a second metal layer disposed on the first insulating layer, wherein the second metal layer forms a scan line, a first connecting metal, and a first drain of the first thin film transistor, and wherein the first drain, the first connection metal, and one end of the scan line are sequentially connected, and the other end of the scan line is connected to the second gate;
a second insulating layer disposed on the second metal layer; and
a third metal layer disposed on the second insulating layer, wherein the third metal layer is electrically connected to the first gate, and a portion of the third metal layer opposite to the first connecting metal forms the bootstrap capacitor.

9. The array substrate of claim 8, wherein the first metal layer is further formed with a common electrode line that is electrically connected to the pixel units.

10. The array substrate of claim 9, wherein a portion of the first connecting metal is opposite to the common electrode line.

11. The array substrate of claim 10, wherein the third metal layer comprises a first region and a second region that are connected to each other, the first region and the first connecting metal have same shape and size and face each other, and the second region is electrically connected to the first gate.

12. The array substrate of claim 11, wherein the second region is electrically connected to the first gate through a third metallized hole penetrating the first insulating layer and the second insulating layer.

13. The array substrate of claim 11, wherein the second metal layer is further formed with a second connecting metal, the first insulating layer is provided with at least one first metallized hole, the second insulating layer is provided with at least one second metallized hole, and the second region, the second metallized hole, the second connection metal, the first metallized hole, and the first gate are electrically connected in sequence.

14. The array substrate of claim 13, wherein the at least one first metallized hole comprises a plurality of first metallized holes arranged in a rectangular array; and the at least one second metallized hole comprises a plurality of second metallized holes arranged in a rectangular array.

15. The array substrate of claim 8, wherein the first insulating layer is provided with at least one fourth metallized hole, and the scan line is electrically connected to the second gate through the fourth metallized hole.

16. The array substrate of claim 15, wherein the at least one fourth metallized hole comprises a plurality of fourth metallized holes arranged in a rectangular array.

17. A display panel comprising an array substrate, wherein the array substrate is provided with a gate driver on array (GOA) driving circuit and a plurality of pixel units, the GOA driving circuit comprises a bootstrap capacitor and a first thin film transistor, and the pixel units comprise a second thin film transistor, the array substrate comprising:
a substrate;
a first metal layer disposed on the substrate, wherein the first metal layer forms a first gate of the first thin film transistor and a second gate of the second thin film transistor;
a first insulating layer disposed on the first metal layer and the substrate;
a second metal layer disposed on the first insulating layer, wherein the second metal layer forms a scan line, a first connection metal, and a first drain of the first thin film transistor, and wherein the first drain, the first connection metal, and one end of the scan line are sequentially connected, and the other end of the scan line is connected to the second gate;
a second insulating layer disposed on the second metal layer; and
a third metal layer disposed on the second insulating layer, wherein the third metal layer is electrically connected to the first gate, and a portion of the third metal layer opposite to the first connecting metal forms the bootstrap capacitor.

18. The display panel of claim 17, wherein the first metal layer is further formed with a common electrode line that is electrically connected to the pixel units.

19. The display panel of claim 18, wherein a portion of the first connecting metal is opposite to the common electrode line.

20. The display panel of claim 19, wherein the third metal layer comprises a first region and a second region that are connected to each other, the first region and the first connecting metal have same shape and size and face each other, and the second region is electrically connected to the first gate.
